(19) United States
(12) Patent Application Publication
(10) Pub. No.: US 2006/0268601 A1
(43) Pub. Date: Nov. 30, 2006

(54) Display device

(76) Inventor: Keun-Kyu Song, Yongin-si (KR)

Correspondence Address: CANTOR COLBURN, LLP, 55 GRIFFIN ROAD SOUTH, BLOOMFIELD, CT, 06002, US

(21) Appl. No.: 11/434,046

(22) Filed: May 15, 2006

(30) Foreign Application Priority Data
May 13, 2005 (KR) 10-2005-40120

(51) Int. Cl. G11C 11/00

(52) U.S. Cl. 365/158

(57) ABSTRACT

A display device according to an embodiment of the present invention includes: a first electrode and a second electrode disposed on a substrate; a nanowire including a semiconductor core disposed on the first electrode, an inner cover enclosing the semiconductor core, and an outer cover enclosing the inner cover; a fixer disposed on the first electrode and the nanowire; and a pixel electrode connected to the nanowire and including a transparent electrode and a reflective electrode, wherein the semiconductor core includes a first portion and a second portion that are not covered with the inner cover, the outer cover, and the fixer, the first portion of the semiconductor core is connected to the second electrode, and the second portion of the semiconductor core is connected to the pixel electrode.

### CROSS-REFERENCE RELATED APPLICATION

This Application claims priority to Korean patent application number 10-2005-0040120, filed on May 13, 2005, and all the benefits accruing therefrom under 35 U.S.C. §119, and the contents of which in its entirety are herein incorporated by reference.

### BACKGROUND OF THE INVENTION

(a) Field of the Invention

The present invention relates to a display device.

(b) Description of the Related Art

Cathode ray tubes (CRT) for displaying images are being substituted with liquid crystal display (LCD), organic light emitting diode display (OLED display), etc. Although a display area for actually displaying images becomes large, electrical circuits for controlling the display area becomes small, such that the size of the display device becomes small.

The display device becomes much smaller by integrating transistors into a substrate. Each pixel forming the display area, as well as driving circuits, includes a transistor. As the size of the transistor becomes small, the aperture ratio of the pixel becomes high to improve the image quality of the display device.

A transistor generally includes an output electrode, an input electrode, a control electrode, and a semiconductor member. The driving performance of the transistor depends on the characteristics of the semiconductor member.

Silicon that is most widely used semiconductor is classified into polysilicon, amorphous silicon, monocrystalline silicon, etc.

Amorphous silicon film can be deposited under a low temperature and thus amorphous silicon transistors are usually used for large display panels. However, amorphous silicon has field effect mobility lower than polysilicon and single crystalline silicon.

On the other hand, although polysilicon and single crystalline silicon have good field effect mobility, polysilicon and single crystalline silicon are made by complicated processes.

### SUMMARY OF THE INVENTION

A display device according to an embodiment of the present invention includes: a first electrode and a second electrode disposed on a substrate; a nanowire including a semiconductor core disposed on the first electrode, an inner cover enclosing the semiconductor core, and an outer cover enclosing the inner cover; a fixer disposed on the first electrode and the nanowire; and a pixel electrode connected to the nanowire and including a transparent electrode and a reflective electrode, wherein the semiconductor core includes a first portion and a second portion that are not covered with the inner cover, the outer cover, and the fixer, the first portion of the semiconductor core is connected to the second electrode, and the second portion of the semiconductor core is connected to the pixel electrode.

The first and the second portions of the semiconductor core may be disposed at opposite ends of the semiconductor core. At least one portion of the second electrode may be disposed on the fixer.

The inner cover may include an insulator such as silicon oxide or silicon nitride. The outer cover may include a conductor such as Al, Cr, Mo, Cu, Ti, and Ta.

The display device may further include: a common electrode facing the pixel electrode; and a liquid crystal layer disposed between the pixel electrode and the common electrode.

The transparent electrode may include a first portion overlapping the reflective electrode and a second portion that does not overlap the reflective electrode to be exposed, and a thickness of the liquid crystal layer may be different on between the first portion and the second portion of the transparent electrode.

A surface of the fixer may have an embossment, and the pixel electrode may have an unevenness following the embossment of the fixer.

The transparent electrode may be disposed on the substrate and the fixer, and the reflective electrode may be disposed on the fixer.

The second electrode may be disposed on the same layer as the reflective electrode.

The display device may further include a passivation layer disposed on the pixel electrode and the second electrode.

### BRIEF DESCRIPTION OF THE DRAWINGS

FIG. 1 is a layout view of a nanowire transistor array panel according to an embodiment of the present invention;

FIG. 2 is an expanded view of a portion of the nanowire transistor array panel shown in FIG. 1;

FIG. 3 is a perspective view of a nanowire shown in FIG. 2;

FIG. 4 is a sectional view of an LCD including the nanowire transistor array panel shown in FIG. 1 taken along line IV-IV;

FIG. 5 is a layout view of the nanowire transistor array panel for an LCD shown FIGS. 1 and 3 in an intermediate step of a manufacturing method thereof according to an embodiment of the present invention;

FIG. 6 is a sectional view of the nanowire transistor array panel shown in FIG. 5 taken along line VI-VI;

FIG. 7 is a layout view of the nanowire transistor array panel shown FIGS. 1 and 3 in the step following the step shown in FIG. 5;

FIG. 8 is a sectional view of the nanowire transistor array panel shown in FIG. 7 taken along line VIII-VIII;

FIG. 9 is a layout view of the nanowire transistor array panel shown FIGS. 1 and 3 in the step following the step shown in FIG. 7; and

FIG. 10 is a sectional view of the nanowire transistor array panel shown in FIG. 9 taken along line X-X.

### DETAILED DESCRIPTION OF EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein. Like numerals refer to like elements throughout.

In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

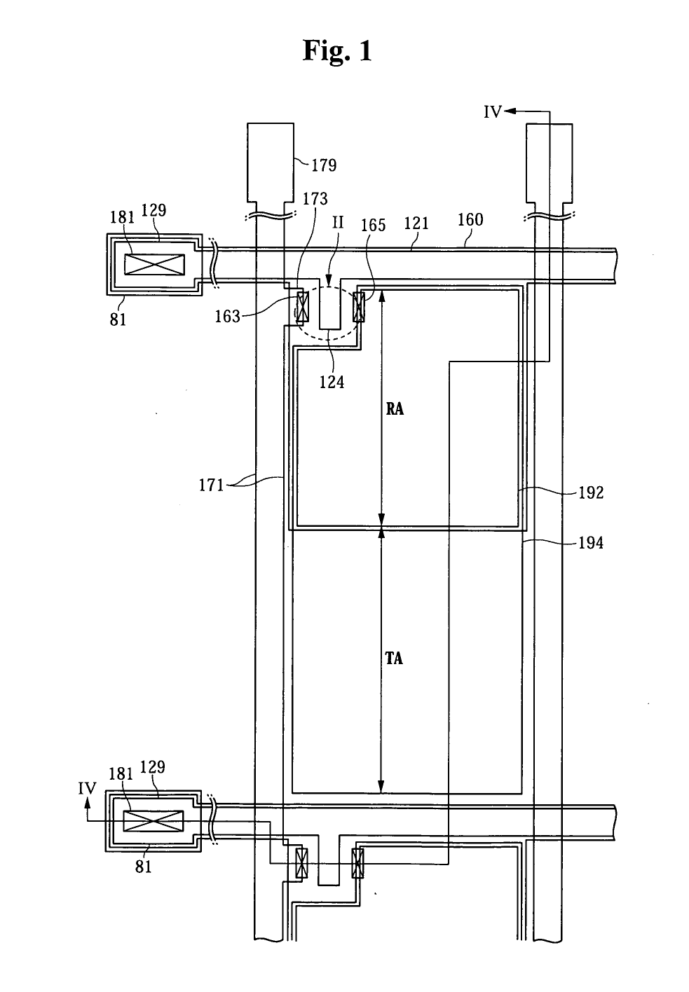

An LCD as an example of a display device according to an embodiment of the present invention will be described in detail with reference to FIGS. 1, 2, 3 and 4.

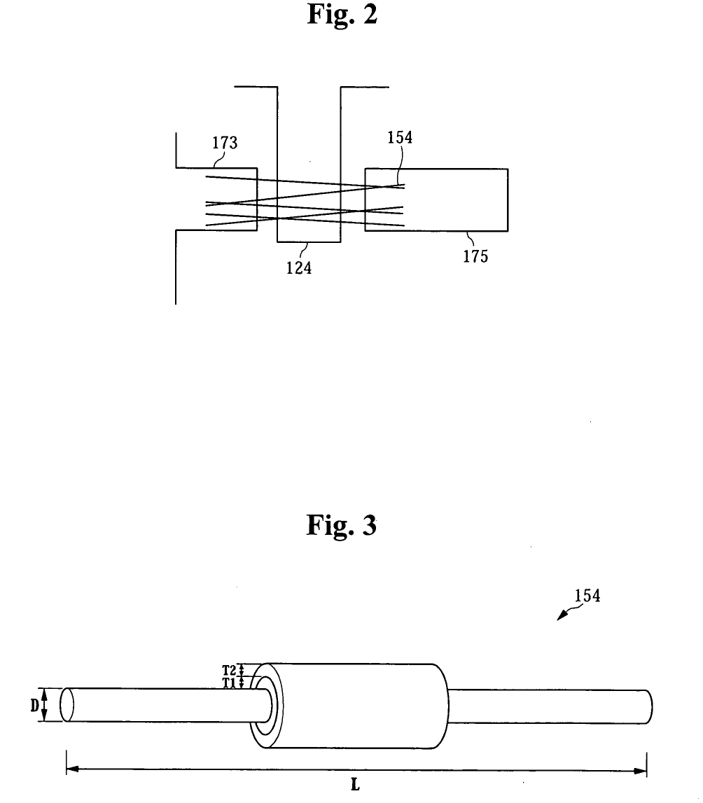

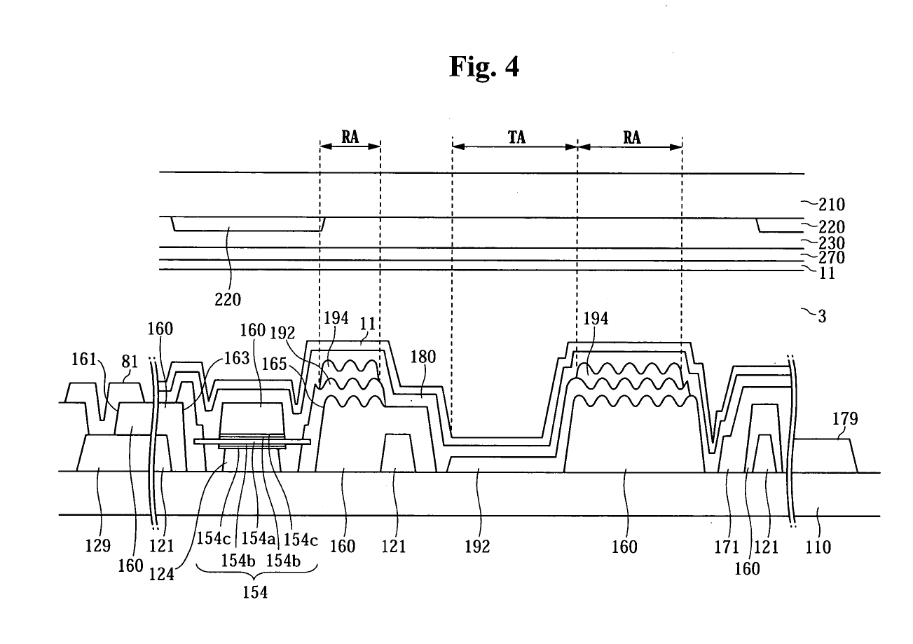

FIG. 1 is a layout view of a nanowire transistor array panel according to an embodiment of the present invention, FIG. 2 is an expanded view of a portion of the nanowire transistor array panel shown in FIG. 1, FIG. 3 is a perspective view of a nanowire shown in FIG. 2, and FIG. 4 is a sectional view of an LCD including the nanowire transistor array panel shown in FIG. 1 taken along line IV-IV.

Referring to FIGS. 1-4, an LCD according to an embodiment of the present invention includes a nanowire transistor array panel 100, a common electrode panel 200 facing the nanowire transistor array panel 100, and a liquid crystal layer 3 interposed between the panels 100 and 200.

First, the common electrode panel 200 will be described.

A light blocking member 220 referred to as a black matrix is formed on an insulating substrate 210 such as transparent glass or plastic. The light blocking member 220 may have a single-layer structure including Cr, or a dual-layered structure including Cr and Cr oxide. Otherwise, the light blocking member 220 may include an organic layer including black pigment.

A plurality of color filters 230 are also formed on the substrate 210. The color filters 230 may represent one of the primary colors such as red, green and blue colors. Adjacent color filters 230 may overlap each other.

A common electrode 270 is formed on the color filters 230. The common electrode 270 may be made of transparent conductive material such as indium tin oxide (ITO) and indium zinc oxide (IZO).

An overcoat (not shown) may be formed between the color filters 230 and the common electrode 270. The overcoat may prevent the color filters 230 from being exposed and provides a flat surface.

The description of the nanowire transistor panel 100 follows.

A plurality of gate lines 121 are also formed on an insulating substrate 110 such as transparent glass or plastic.

The gate lines 121 transmit gate signals and extend substantially in a transverse direction. Each of the gate lines 121 includes a plurality of gate electrodes 124 projecting downward and an end portion 129 having a large area for contact with another layer or an external driving circuit. The gate electrodes 124 are disposed on the outer covers 154c of the nanowires 154. The gate electrodes 124 have boundaries coinciding with boundaries the inner covers 154b and the outer covers 154c of the nanowires 154, and are separated apart from the semiconductor cores 154a. A gate driving circuit (not shown) for generating the gate signals may be mounted on a flexible printed circuit (FPC) film (not shown), which may be attached to the substrate 110, directly mounted on the substrate 110, or integrated onto the substrate 110. The gate lines 121 may extend to be connected to a driving circuit that may be integrated on the substrate 110.

The gate lines 121 and the storage electrode lines 131 may be made of Al containing metal such as Al and Al alloy, Ag containing metal such as Ag and Ag alloy, Cu containing metal such as Cu and Cu alloy, Au containing metal such as Au and Au alloy, Mo containing metal such as Mo and Mo alloy, Cr, Ta, or Ti. However, they may have a multi-layered structure including two conductive films (not shown) having different physical characteristics. One of the two films may be made of low resistivity metal including Al containing metal, Ag containing metal, and Cu containing metal for reducing signal delay or voltage drop. The other film may be made of material such as Mo containing metal, Cr, Ta, or Ti, which has good physical, chemical, and electrical contact characteristics with other materials such as indium tin oxide (ITO) or indium zinc oxide (IZO). Good examples of the combination of the two films are a lower Cr film and an upper Al (alloy) film and a lower Al (alloy) film and an upper Mo (alloy) film. However, the gate lines 121 and the storage electrode lines 131 may be made of various metals or conductors.

The lateral sides of the gate lines 121 are inclined relative to a surface of the substrate 110, and the inclination angle thereof ranges about 30-80 degrees.

A plurality of nanowires 154 are also formed on the gate lines 121.

Referring to FIG. 2, the nanowires 154 cross over the gate lines 124 and are aligned irregularly. For example, the nanowires 154 meet each other. However, the nanowires 154 may be aligned substantially parallel to each other in a two-dimensional plane or may be laminated in a three-dimensional space.

Referring to FIG. 3, each of the nanowires 154 includes a semiconductor core 154a, an inner cover 154b, and an outer cover 154c. The semiconductor core 154a may be made of single crystalline semiconductor having a size of nanometers. The inner cover 154b covers the semiconductor core 154a, and the outer cover 154c covers the inner cover 154b. The outer cover 154c and the inner cover 154b enclose a center portion of the semiconductor core 154a and end portions of the semiconductor core 154a are exposed.

Material for the semiconductor core 154a includes any semiconductor that can be made to have a nanometer size. Examples of the material for the semiconductor core 154a include Si, Ge, and III-V compound semiconductor. The semiconductor core 154a is lightly doped with conductive impurity ions including P type impurity such as B, Ga, etc., and N type impurity such as P, As, etc. The semiconductor core 154a has a diameter D equal to about 18-22 nm and a length L equal to about 30-60 microns.

The inner cover 154b may be made of silicon oxide SiO₂ or silicon nitride SiNx, and the outer cover 154c may be made of conductive material such as Al, Cr, Mo, Cu, Ti, Ta, etc. Each of the thickness T1 of the inner cover 154b and the thickness T2 of the outer cover 154c may be equal to about 20-25 nm.

A plurality of fixers 160 are formed on the nanowires 154, the gate lines 121, and the substrate 110. The fixers 160 extend along the gate lines 121 to fix the nanowires 154 on the gate lines 121, and include a plurality of wide portions extending downward.

The fixers 160 may be made of inorganic or organic insulator and they have embossments. Examples of the inorganic insulator include silicon nitride and silicon oxide. The organic insulator may have photosensitivity and dielectric constant less than about 4.0. The fixers 160 may include a lower film of inorganic insulator and an upper film of organic insulator.

The fixers 160 have a plurality of contact holes 161, 163 and 165. The contact holes 161 expose the end portions 129 of the gate lines 121 and the contact holes 163 and 165 expose the exposed portions of the semiconductor cores 154a. The edges of the contact holes 163 and 165 coincide with edges of the inner covers 154b and the outer covers 154c of the nanowires 154.

A plurality of data lines 171, a plurality of pixel electrodes 191, and a plurality of contact assistants 81 are formed on the fixers 160 and the substrate 110.

The data lines 171 transmit data signals and extend substantially in the longitudinal direction to intersect the gate lines 121. Each of the data lines 171 includes a plurality of input electrodes 173 and an end portion 179 having a large area for contact with another layer or an external driving circuit. The input electrodes 173 are connected to the semiconductor cores 154a through the contact holes 163 and parts of edges of the input electrodes 173 are disposed in the contact holes 163. The end 179 has a large area for contact with another layer or an external driving circuit. A data driving circuit (not shown) for generating the data signals may be mounted on a FPC film (not shown), which may be attached to the substrate 110, directly mounted on the substrate 110, or integrated onto the substrate 110. The data lines 171 may extend to be connected to a driving circuit that may be integrated on the substrate 110.

Each of the pixel electrodes 191 has unevenness following the embossment of a fixer 160 and includes a transparent electrode 192 and a reflective electrode 194 disposed thereon.

The transparent electrode 192 is disposed on the fixer 160 and the substrate, and the reflective electrode 194 is disposed on a portion of the transparent electrode 192 opposite the fixer 160. The reflective electrode 194 may cover an entire area of the transparent electrode 192 and may have a transmission window exposing a portion of the transparent electrode 192.

The transparent electrodes 192 and the contact assistants 81 may be made of transparent conductor such as ITO or IZO. The data lines 171 and the reflective electrodes 194 may be made of refractory metal such as Al containing metal, Ag containing metal, Cu containing metal, Au containing metal, Mo containing metal, Cr, Ta, or Ti. However, the data lines 171 and the reflective electrodes 194 may have a multilayered structure including a good contact lower film (not shown) of Mo containing metal, Cr, Ta, or Ti and a reflective low-resistivity upper film (not shown) of Al, Ag or alloys thereof.

The pixel electrodes 191 are physically and electrically connected to the semiconductor cores 154a through the contact holes 165. A portion of each of the pixel electrodes 191, which is connected to a semiconductor core 154a, is used as an output electrode to receive data voltages from the semiconductor core 154a.

A gate electrode 124, an input electrode 173, and an output electrode 175 along with at least one of the nanowires 154 form a transistor having a channel formed in the semiconductor cores 154a disposed interior to the inner covers 154b of the nanowires 154.

A transistor including single crystalline nanowires has superior driving performance than an amorphous or polysilicon thin film transistor.

The pixel electrodes 191 supplied with the data voltages generate electric fields in cooperation with a common electrode 270 of the common electrode panel 200 supplied with a common voltage, which determine the orientations of liquid crystal molecules 31 of the liquid crystal layer 3 disposed between the two electrodes 191 and 270. A pixel electrode 191 and the common electrode 270 form a capacitor referred to as a “liquid crystal capacitor,” which stores applied voltages after the nanowire transistor turns off.

In the meantime, a pixel of a transflective LCD includes a transmissive region TA and a reflective region RA defined by a transparent electrode 192 and a reflective electrode 194. In detail, the transmissive region TA includes portions of the nanowire transistor array panel 100, the common electrode panel 200, and the liquid crystal layer 3, which are disposed on and under the exposed portion of the transparent electrode 192, while the reflective region RA includes portions of the nanowire transistor array panel 100, the common electrode panel 200, and the liquid crystal layer 3, which are disposed on and under the reflective electrode 194. In the transmissive region TA, a light enters from a rear surface of the LCD, i.e., from the nanowire transistor array panel 100, passes through the liquid crystal layer 3, and comes out of a front surface of the LCD, i.e., out of the common electrode panel 200, thereby displaying images. In the reflective region RA, an incident light from the front surface passes through the liquid crystal layer 3, is reflected by the reflective electrode 194, and passes through the liquid crystal layer 3 again to come out of the front surface, thereby displaying images.

The contact assistants 81 are connected to the end portions 129 of the gate lines 121 through the contact holes 161. The contact assistants 81 protect the end portions 129 and enhance the adhesion between the end portions 129 and external devices.

A passivation layer 180 is formed on the data lines 171 and the pixel electrodes 191. The passivation layer 180 protects the data lines 171 and the pixel electrodes 191 and stabilizes the nanowire transistors. The passivation layer 180 may be made of inorganic or organic insulator like the fixers 160. When the passivation layer 180 is made of an organic insulator, the fixers 160 may cover an entire surface of the nanowire transistor array panel 100 with a uniform thickness and the passivation layer 180 may have a position-dependent thickness.

The passivation layer 180 does not cover the end portions 129 of the gate lines 121 and the end portions 179 of the data lines 17 to expose the end portions 129 and 179.

Alignment layers 11 and 21 that may be homeotropic or homogeneous are coated on inner surfaces of the panels 100 and 200, and polarizers (not shown) are provided on outer surfaces of the panels 100 and 200 so that their polarization axes may be crossed or parallel to each other.

The LCD may further include at least one retardation film (not shown) for compensating the retardation of the LC layer 3. The retardation film has birefringence and reversely compensates for the birefringence of the liquid crystal layer 3. The retardation film may include uniaxial or biaxial optical film. In particular, negative uniaxial optical film may be preferred.

A plurality of spacers (not shown) are disposed between the nanowire transistor panel 100 and the common electrode panel 200. The spacers may be made of insulating material and keeps a gap between the panels 100 and 200 constant.

The LCD may further include a backlight unit (not shown) supplying light to the LC layer 3 through the polarizers 12 and 22, the retardation film, and the panels 100 and 200.

The liquid crystal layer 3 may be aligned in a vertical alignment (VA) mode or in a twisted nematic (TN) mode. Otherwise, the liquid crystal layer 3 may include liquid crystal molecules having bend or splay alignment that is symmetrical with respect to a midplane between the substrates 110 and 210. The thickness of the liquid crystal layer 3 is different between the reflective region RA and the transmissive region TA, and in particular, a portion of the liquid crystal layer 3 in the reflective region RA is thinner than a portion thereof in the transmissive region TA.

As described above, since a nanowire transistor includes single crystalline nanowires, it has superior driving performance than an amorphous or polysilicon thin film transistor. Therefore, the nanowire can have a size smaller than a conventional thin film transistor to increase the aperture ratio.

In addition, the nanowire transistors may be included in a gate driver or a data driver such that the drivers are integrated in the panel 100.

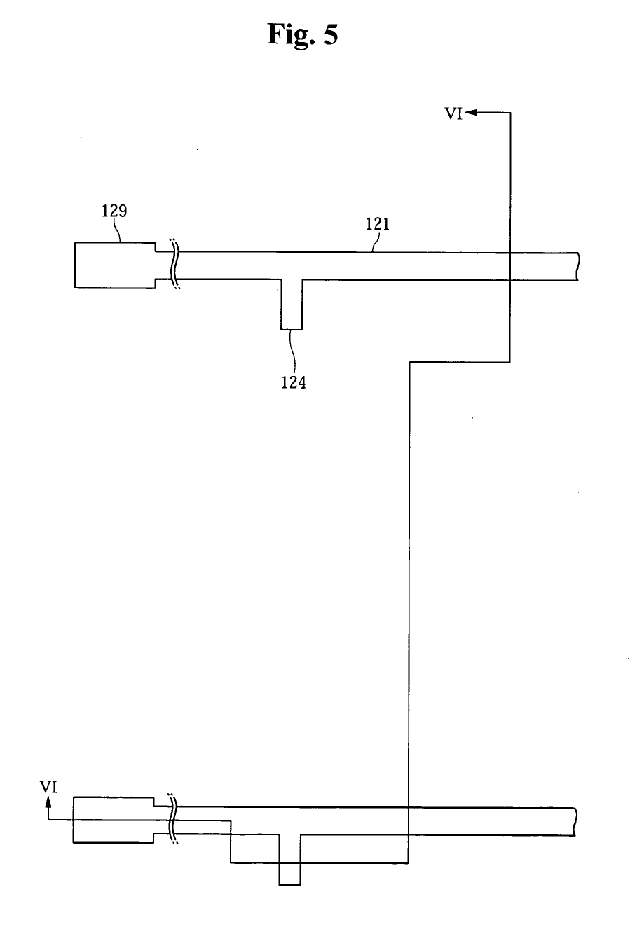

Now, a method of manufacturing the nanowire transistor array panel shown in FIGS. 1-4 according to an embodiment of the present invention will be described in detail with reference to FIGS. 5-10 as well as FIGS. 1-4.

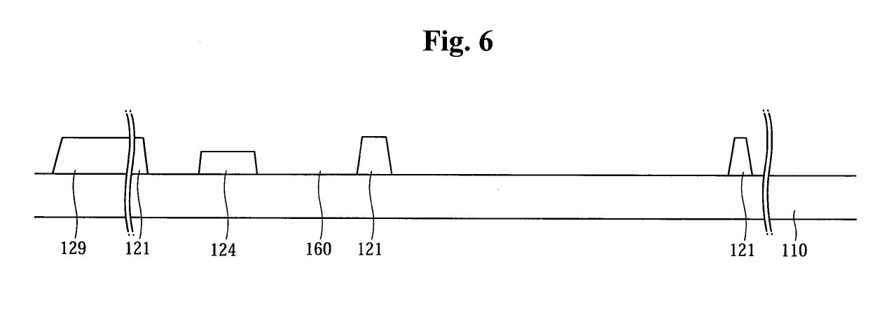

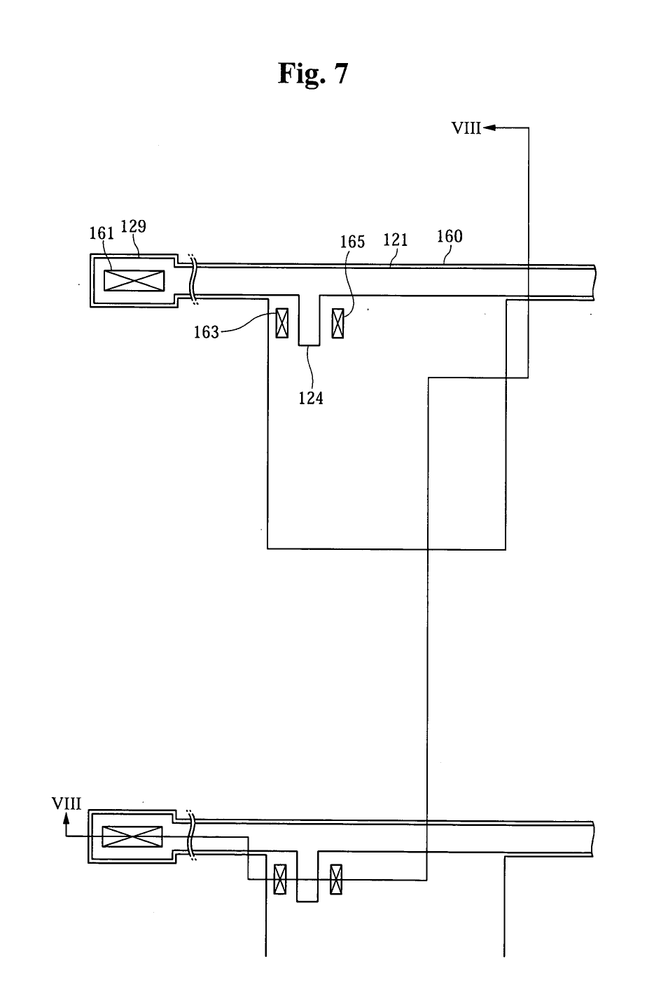

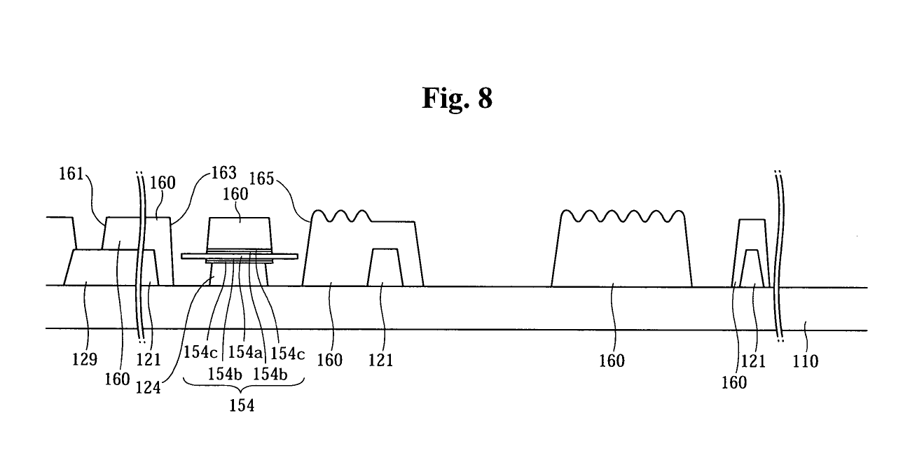

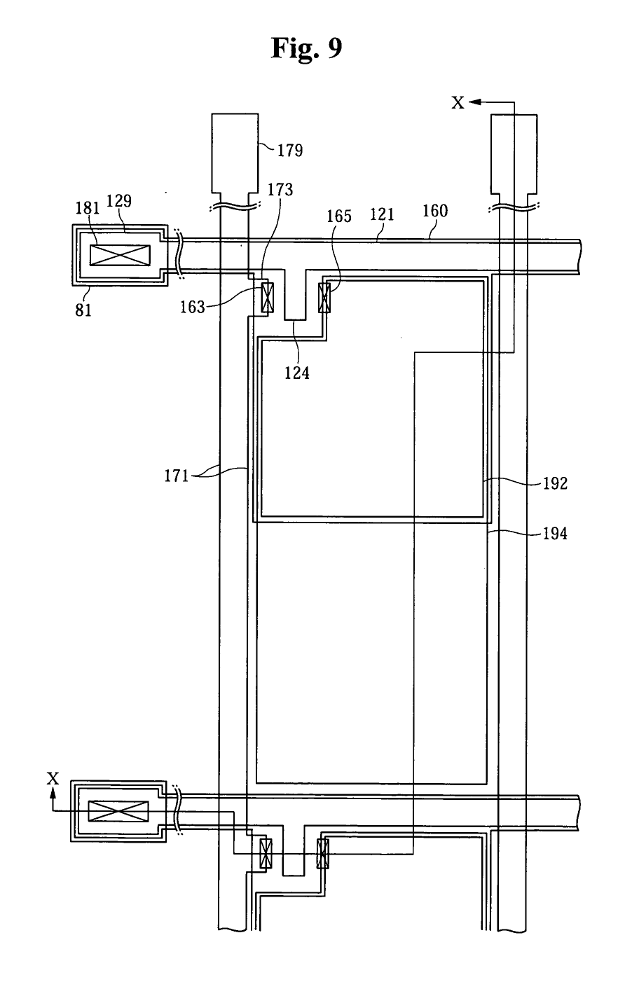

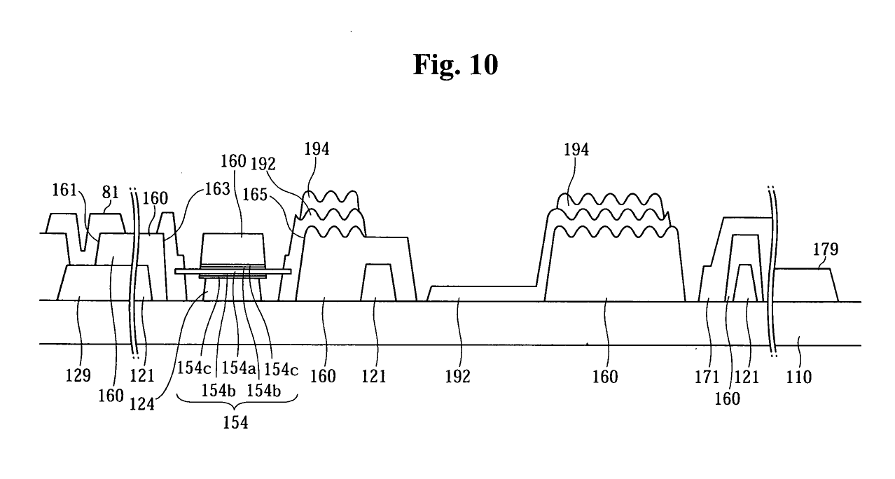

FIG. 5 is a layout view of the nanowire transistor array panel for an LCD shown FIGS. 1 and 4 in an intermediate step of a manufacturing method thereof according to an embodiment of the present invention, FIG. 6 is a sectional view of the nanowire transistor array panel shown in FIG. 5 taken along lines VI-VI, FIG. 7 is a layout view of the nanowire transistor array panel shown FIGS. 1 and 4 in the step following the step shown in FIG. 5, FIG. 8 is a sectional view of the nanowire transistor array panel shown in FIG. 7 taken along lines VIII-VIII, FIG. 9 is a layout view of the nanowire transistor array panel shown FIGS. 1 and 4 in the step following the step shown in FIG. 7, and FIG. 10 is a sectional view of the nanowire transistor array panel shown in FIG. 9 taken along lines X-X.

Referring to FIGS. 5 and 6, a conductive layer is deposited by sputtering, etc., and patterned in photolithography and etch to form a plurality of gate lines 121 including gate electrodes 124 and end portions 129.

Referring to FIGS. 7 and 8, nanowires 154 including semiconductor cores 154a covered with inner covers 154b and outer covers 154c are spread on a transparent insulating substrate 110. The nanowires 154 may be put into liquid such as ethanol or photoresist to form a mixture and the mixture may be coated on the substrate 110.

Examples of the coating method include gravure coating, meyer rod coating, doctor blade coating, spin coating, slit coating, and inkjet print. The mixture including the nanowires 154 may be flowed in a predetermined direction on the substrate 110 or a mold having trenches that can receive the nanowires 154 may be formed before the mixture coating, such that the nanowires 154 are aligned in a direction.

When using ethanol, ethanol is evaporated after the coating to remain the nanowires 154 on the substrate 110.

An insulating layer is deposited and patterned by lithography (and etch) to form a plurality of fixers 160 having contact holes 161, 163 and 165 and having embossments. Then, some of the nanowires 154 spaced apart from the fixers 160 are fully exposed, and other of the nanowires 154 are partly covered with the fixers 160 and partly exposed out of the fixers 160.

The fully exposed nanowires 154 are removed from the substrate 110. And then, portions of the outer covers 154c and the inner covers 154b of the partly exposed nanowires 154 are etched to expose portions of the semiconductor core 154a. The outer covers 154c may be wet etched and the inner covers 154b may be dry or wet etched.

In this way, both end portions of some of the spread nanowires 154 are exposed as shown in FIG. 3.

Referring to FIGS. 9 and 10, ITO or IZO is deposited and patterned by photolithography and etching to form a plurality of pixel electrodes 191 and a plurality of contact assistants 81. Thereafter, a conductive layer is deposited by sputtering, etc., and patterned by photolithography and etch to form a plurality of data lines 171 and a plurality of reflective electrodes 194. At this time, the data lines 171 and the pixel electrodes 191 may be sufficiently spaced apart from the gate electrodes 124 and the conductive outer covers 154c of the nanowires 154 disposed thereon.

Finally, a passivation layer 180 of an inorganic insulator, etc., is deposited and portions of the passivation layer 180 disposed on the end portions 129 of the gate lines 121 and the end portions 179 of the data lines 171 are removed as shown in FIGS. 1 and 4.

In this way, a display panel including excellent transistors is formed by small number of process steps without complicated process steps such as doping impurity or crystallization.

As described above, the nanowire transistors according to the embodiments of the present invention provide a display panel without complicated process steps to reduce the production cost.

Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. A display device comprising:
a first electrode and a second electrode disposed on a substrate;
a nanowire comprising a semiconductor core disposed on the first electrode, an inner cover enclosing the semiconductor core, and an outer cover enclosing the inner cover;
a fixer disposed on the first electrode and the nanowire; and
a pixel electrode connected to the nanowire and comprising a transparent electrode and a reflective electrode,
wherein the semiconductor core comprises a first portion and a second portion that are not covered with the inner cover, the outer cover, and the fixer, the first portion of the semiconductor core is connected to the second electrode, and the second portion of the semiconductor core is connected to the pixel electrode.

2. The display device of claim 1, wherein the first and the second portions of the semiconductor core are disposed at opposite ends of the semiconductor core.

3. The display device of claim 1, wherein at least one portion of the second electrode is disposed on the fixer.

4. The display device of claim 1, wherein the inner cover comprises an insulator.

5. The display device of claim 1, wherein the inner cover comprises silicon oxide or silicon nitride.

6. The display device of claim 1, wherein the outer cover comprises a conductor.

7. The display device of claim 6, wherein the outer cover comprises at least one of Al, Cr, Mo, Cu, Ti, and Ta.

8. The display device of claim 1, further comprising:
a common electrode facing the pixel electrode; and
a liquid crystal layer disposed between the pixel electrode and the common electrode.

9. The display device of claim 8, wherein the transparent electrode comprises a first portion overlapping the reflective electrode and a second portion that does not overlap the reflective electrode to be exposed, and a thickness of the liquid crystal layer is different between the first portion and the second portion of the transparent electrode.

10. The display device of claim 1, wherein a surface of the fixer has an embossment.

11. The display device of claim 10, wherein the pixel electrode has an unevenness following the embossment of the fixer.

12. The display device of claim 1, wherein the transparent electrode is disposed on the substrate and the fixer.

13. The display device of claim 12, wherein the reflective electrode is disposed on the fixer.

14. The display device of claim 1, wherein the second electrode is disposed on the same layer as the reflective electrode.

15. The display device of claim 1, further comprising a passivation layer disposed on the pixel electrode and the second electrode.
